(19) United States
(12) Patent Application Publication
(10) Pub. No.: US 2018/0258532 A1
(43) Pub. Date: Sep. 13, 2018

(54) SHOWER PLATE, PROCESSING APPARATUS, AND EJECTION METHOD

(71) Applicant: Kabushiki Kaisha Toshiba, Minato-ku (JP)

(72) Inventors: Shiguma KATO, Yokohama (JP); Takahiro Terada, Yokohama (JP); Takayuki Masunaga, Yokohama (JP); Makoto Ootaki, Kawasaki (JP); Hitoshi Hasegawa, Yokohama (JP); Kosuke Adachi, Yokohama (JP); Satoshi Tsuno, Yokohama (JP)

(73) Assignee: Kabushiki Kaisha Toshiba, Minato-ku (JP)

(21) Appl. No.: 15/914,585

(22) Filed: Mar. 7, 2018

(30) Foreign Application Priority Data
Mar. 8, 2017 (JP) 2017-044260

(51) Int. Cl. C23C 16/455

(52) U.S. Cl. CPC C23C 16/45565

(57) ABSTRACT

According to an embodiment, a shower plate includes a first member and a second member. The first member includes a first wall provided with a plurality of first openings and internally including a room with which the first openings communicate. The second member includes a second wall provided with a second opening and arranged in the room. The second member is arranged at a position spaced apart from the first member, and allows one of the first openings facing the second opening to be replaced with another of the first openings by changing a position of the second member with respect to the first member.

### CROSS-REFERENCE TO RELATED APPLICATIONS

This application is based upon and claims the benefit of priority from Japanese Patent Application No. 2017-044260, filed on Mar. 8, 2017, the entire contents of which are incorporated herein by reference.

### FIELD

Embodiments described herein relate generally to a shower plate, a processing apparatus, and an ejection method.

### BACKGROUND

A shower plate for ejecting a fluid from a plurality of openings is known. For example, in order to change ejection positions of the fluid for each of types of fluid, there are cases where a plurality of first openings communicating with a space where a first fluid diffuses and a plurality of second openings communicating with a space where a second fluid diffuses are separately provided on the shower plate.

### BRIEF DESCRIPTION OF THE DRAWINGS

FIG. 1 is a cross-sectional view schematically illustrating a semiconductor manufacturing apparatus according to a first embodiment;

FIG. 2 is a cross-sectional view illustrating a shower plate in the first embodiment;

FIG. 3 is a bottom view illustrating the shower plate in the first embodiment;

FIG. 4 is a bottom view illustrating a first moving wall in the first embodiment;

FIG. 5 is a bottom view illustrating a shower plate on which a second member rotates in the first embodiment;

FIG. 6 is a bottom view illustrating the shower plate after rotation of the second member in the first embodiment;

FIG. 7 is a bottom view illustrating a shower plate according to a modification of the first embodiment;

FIG. 8 is a bottom view illustrating a shower plate according to a second embodiment;

FIG. 9 is a bottom view illustrating a first moving wall in the second embodiment;

FIG. 10 is a cross-sectional view of a shower plate according to a third embodiment;

FIG. 11 is a cross-sectional view of a shower plate according to a fourth embodiment;

FIG. 12 is a bottom view of the shower plate in the fourth embodiment; and

FIG. 13 is a cross-sectional view of a shower plate according to a modification of the fourth embodiment.

### DETAILED DESCRIPTION

According to an embodiment, a shower plate includes a first member and a second member. The first member includes a first wall provided with a plurality of first openings and internally including a room with which the first openings communicate. The second member includes a second wall provided with a second opening and arranged in the room. The second member is arranged at a position spaced apart from the first member, and allows one of the first openings facing the second opening to be replaced with another of the first openings by changing a position of the second member with respect to the first member.

### First Embodiment

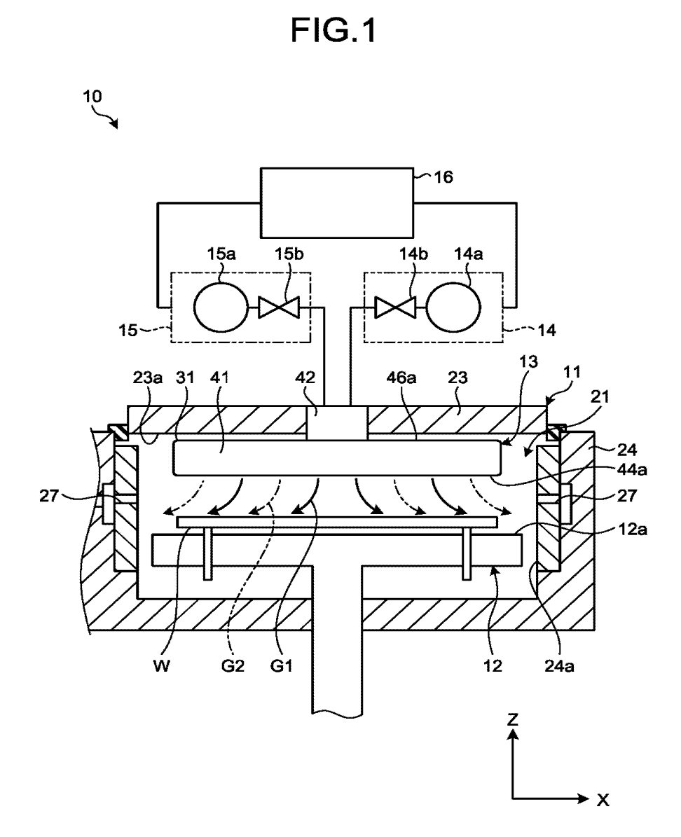

Hereinafter, a first embodiment will be described with reference to FIGS. 1 to 6. The present description basically defines a vertically upward direction as an upper or upward direction, and defines a vertically downward direction as a lower or downward direction. Moreover, the present description may include a plurality of expressions for a constituent element according to the embodiment and the description of the element. The constituent element and description written with the plurality of expressions may be expressed in other non-described manners. Furthermore, the constituent element and description not described with a plurality of expressions may also be expressed in other non-described manners.

FIG. 1 is a cross-sectional view schematically illustrating a semiconductor manufacturing apparatus 10 according to the first embodiment. The semiconductor manufacturing apparatus 10 is an exemplary processing apparatus and may also be referred to as a manufacturing apparatus, a machining apparatus, an ejection apparatus, a supply apparatus, and an apparatus, for example. Note that the processing apparatus is not limited to the semiconductor manufacturing apparatus 10, and may represent another apparatus that performs processing such as machining, cleaning, and testing on a target object.

As illustrated in individual drawings, an X-axis, a Y-axis and a Z-axis are defined in the present description. The X-axis, the Y-axis, and the Z-axis are orthogonal to each other. The X-axis is defined along a width of the semiconductor manufacturing apparatus 10. The Y-axis is defined along a depth (length) of the semiconductor manufacturing apparatus 10. The Z-axis is defined along a height of the semiconductor manufacturing apparatus 10. In the present embodiment, the Z-axis extends in the vertical direction. The direction in which the Z-axis extends may be different from the vertical direction.

The semiconductor manufacturing apparatus 10 according to the first embodiment illustrated in FIG. 1 is a chemical vapor deposition (CVD) apparatus, for example. The semiconductor manufacturing apparatus 10 may be another type of apparatus. The semiconductor manufacturing apparatus 10 includes a manufacturing unit 11, a stage 12, a shower plate 13, a first gas supply apparatus 14, a second gas supply apparatus 15, and a control unit 16.

The manufacturing unit 11 may also be referred to as a housing, for example. The stage 12 is an exemplary arrangement unit, and is also referred to as a mounting potion, or a table, for example. The shower plate 13 may also be referred to as a channel structure, an ejection apparatus, a supply apparatus, a jet apparatus, a distribution apparatus, a discharge apparatus, a member, or a component, for example. The first and second gas supply apparatuses 14 and 15 are exemplary supply units.

The manufacturing unit 11 internally includes a chamber 21 that can be hermetically sealed. The chamber 21 may also be referred to as a room or a space, for example. The semiconductor manufacturing apparatus 10 manufactures a semiconductor wafer (hereinafter referred to as a wafer) W in the chamber 21, for example. The wafer W is an exemplary target object. The manufacturing unit 11 includes an upper wall 23 and a side wall 24.

The upper wall 23 includes an inner surface 23a. The inner surface 23a is a substantially flat surface facing downward. The side wall 24 includes an inner side surface 24a. The inner side surface 24a is a surface facing a substantially horizontal direction. The inner surface 23a and the inner side surface 24a form a portion of the chamber 21. That is, the inner surface 23a and the inner side surface 24a face the inside of the chamber 21. The side wall 24 includes a plurality of exhaust ports 27. The gas in the chamber 21 can be sucked from the exhaust port 27.

The stage 12 and the shower plate 13 are arranged in the chamber 21. As illustrated in FIG. 1, a portion of the stage 12 and a portion of the shower plate 13 may be located outside the chamber 21.

The stage 12 includes a support 12a. The support 12a is located in the chamber 21 and supports the wafer W toward the inner surface 23a of the upper wall 23. In other words, the wafer W is arranged on the stage 12. The stage 12 includes a heater, and is capable of heating the wafer W supported by the support 12a.

For example, the stage 12 can fix the wafer W to the support 12a by sucking the wafer W. Furthermore, the stage 12 is connected to a drive apparatus such as a motor, and is rotatable while supporting the wafer W.

The shower plate 13 is attached to the upper wall 23 of the manufacturing unit 11, for example. The shower plate 13 faces the wafer W supported by the support 12a of the stage 12. The shower plate 13 is capable of ejecting a first gas G1 and a second gas G2 to the wafer W as indicated by arrows in FIG. 1.

The first gas G1 is an example of a fluid and a first fluid. The second gas G2 is an example of a fluid and a second fluid. The fluid is not limited to a gas, and may be another fluid such as a liquid.

The first gas G1 forms an oxide film on the wafer W, for example. The second gas G2 forms a nitride film on the wafer W, for example. The first gas G1 and the second gas G2 are not limited to this example. In addition, the first gas G1 and the second gas G2 may be fluids having the same composition.

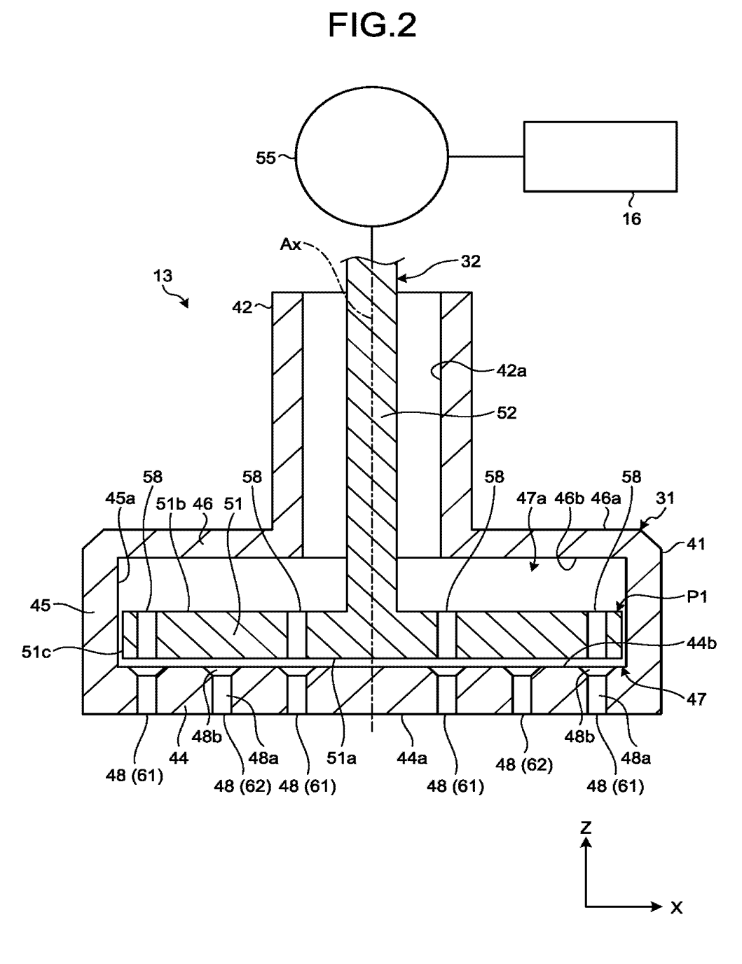

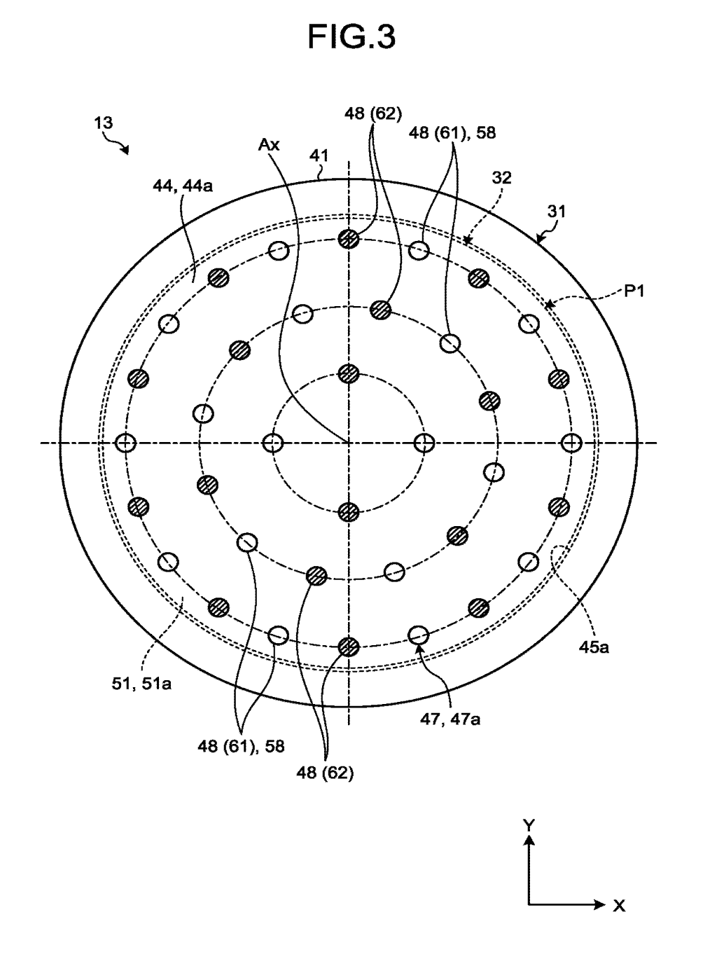

FIG. 2 is a cross-sectional view of the shower plate 13 according to the first embodiment. FIG. 3 is a bottom view illustrating the shower plate 13 in the first embodiment. As illustrated in FIG. 2, the shower plate 13 includes a first member 31 and a second member 32. For example, each of the first member 31 and the second member 32 is formed of a material resistant to the first and second gases G1 and G2, respectively.

The first member 31 includes a diffuser 41 and a tube portion 42. The diffuser 41 has a substantially disk shape spreading on an X-Y plane. The tube portion 42 extends in a positive direction along the Z-axis (direction the Z-axis arrow faces, upward) from a substantially central portion of the diffuser 41.

As illustrated in FIG. 1, the tube portion 42 penetrates the upper wall 23. For example, the tube portion 42 is fixed to the upper wall 23 so as to attach the shower plate 13 to the upper wall 23 of the manufacturing unit 11. The shower plate 13 may be attached to the manufacturing unit 11 by another means.

As illustrated in FIG. 2, the diffuser 41 includes a bottom wall 44, a peripheral wall 45, and a covering wall 46. The bottom wall 44 is an exemplary first wall. Furthermore, the diffuser 41 internally includes a diffusion chamber 47. The diffusion chamber 47 is an example of a room and may also be referred to as a space or a container, for example. The diffusion chamber 47 is surrounded by the bottom wall 44, the peripheral wall 45, and the covering wall 46.

The bottom wall 44 has a substantially disk shape spreading on the X-Y plane. The bottom wall 44 includes a bottom surface 44a and a first inner surface 44b. The bottom surface 44a may also be referred to as an outer surface or a surface, for example. The first inner surface 44b is an exemplary first surface.

The bottom surface 44a is a substantially flat surface facing the negative direction along the Z-axis (direction opposite to the direction in which the arrow of the Z-axis points, downward), and is located at a negative end along the Z-axis of the shower plate 13. In other words, the bottom surface 44a forms a portion of the outer surface of the shower plate 13. The bottom surface 44a may be a curved surface or may have irregularities.

As illustrated in FIG. 1, the bottom surface 44a faces the wafer W supported by the support 12a of the stage 12, via a gap. In other words, the stage 12 supports the wafer W at a position where the bottom surface 44a faces.

As illustrated in FIG. 2, the first inner surface 44b is a substantially flat surface located on the opposite side of the bottom surface 44a and facing the positive direction along the Z-axis. The first inner surface 44b may be a curved surface or may have irregularities. The first inner surface 44b faces the diffusion chamber 47 and forms a portion of the inner surface of the diffusion chamber 47.

The peripheral wall 45 is a substantially cylindrical wall extending from an edge of the bottom wall 44 in the positive direction along the Z-axis. The peripheral wall 45 includes a second inner surface 45a. The second inner surface 45a is an exemplary inner surface of the room. The second inner surface 45a faces the diffusion chamber 47 and forms a portion of the inner surface of the diffusion chamber 47.

The covering wall 46 has a substantially disk shape spreading on the X-Y plane. An edge of the covering wall 46 is connected to an edge of the bottom wall 44 by the peripheral wall 45. The covering wall 46 includes an upper surface 46a and a third inner surface 46b. The third inner surface 46b is an exemplary second surface.

The upper surface 46a is a substantially flat surface facing the positive direction along the Z-axis. The upper surface 46a forms a portion of the outer surface of the shower plate 13. The tube portion 42 extends in the positive direction along the Z-axis from the upper surface 46a.

The third inner surface 46b is located on the opposite side of the upper surface 46a and is a substantially flat surface facing the negative direction along the Z-axis. The third inner surface 46b faces the first inner surface 44b. The third inner surface 46b may be a curved surface or may have irregularities. The third inner surface 46b faces the diffusion chamber 47 and forms a portion of the inner surface of the diffusion chamber 47.

A supply port 42a is provided inside the tube portion 42. The supply port 42a extends in the direction along the Z-axis to open on the third inner surface 46b to communicate with the diffusion chamber 47. The supply port 42a communicates with the first and second gas supply apparatuses 14 and 15 in FIG. 1 via a pipe, for example. That is, the first and second gas supply apparatuses 14 and 15 are connected to the diffusion chamber 47 via the pipe and the supply port 42a.

The bottom wall 44 includes a plurality of first openings 48. The first openings 48 may also be referred to as holes, through holes, and ejection ports. Each of the plurality of first openings 48 communicates with the bottom surface 44a and the first inner surface 44b. In other words, the first openings 48 communicate with the diffusion chamber 47 and the outside of the shower plate 13.

In the present embodiment, the plurality of first openings 48 has substantially the same shape. The plurality of first openings 48 may include a plurality of first openings 48 having mutually different shapes.

Each of the plurality of first openings 48 has a straight portion 48a and a tapering portion 48b. The tapering portions 48b may also be referred to as tapered portions, enlarged diameter portions, receiving portions, or guide portions. The first openings 48 may each have any one of the straight portion 48a and the tapering portion 48b.

The straight portions 48a are substantially circular holes communicating with the bottom surface 44a of the bottom wall 44. The straight portions 48a extend substantially linearly in the direction along the Z-axis. The tapering portions 48b are substantially truncated conical holes communicating with the first inner surface 44b of the bottom wall 44. The tapering portions 48b may have another shape. The tapering portions 48b taper in a direction from the first inner surface 44b toward the bottom surface 44a. That is, portions having the maximum cross-sectional areas of the tapering portions 48b open on the first inner surface 44b. In contrast, portions having the minimum cross-sectional areas of the tapering portions 48b are connected to the straight portions 48a.

The second member 32 includes a first moving wall 51 and a first support 52. The first moving wall 51 is an exemplary second wall. The first support 52 is an exemplary support. The second member 32 is arranged at a position spaced apart from the first member 31. The second member 32 is spaced apart from the first member 31 at least inside the first member 31.

The first moving wall 51 has a substantially disk shape spreading on the X-Y plane. The first moving wall 51, the substantially disk-shaped bottom wall 44 and the covering wall 46, and the substantially cylindrical peripheral wall 45 are arranged to have a center axis Ax in common. The center axis Ax extends in a direction along the Z-axis. The first moving wall 51, the bottom wall 44, the covering wall 46, and the peripheral wall 45 may have mutually different center axes.

The first moving wall 51 is arranged in the diffusion chamber 47 at a position spaced apart from the first member 31. That is, the first moving wall 51 is smaller than the diffusion chamber 47 and contained inside the first member 31. The first moving wall 51 includes a lower surface 51a, an upper surface 51b, and a side surface 51c.

The lower surface 51a is a substantially flat surface facing the negative direction along the Z-axis. The lower surface 51a faces the first inner surface 44b of the bottom wall 44 via a gap. In other words, the first inner surface 44b of the bottom wall 44 faces the lower surface 51a of the first moving wall 51 via a gap. The distance between the first inner surface 44b and the lower surface 51a is set substantially uniformly.

The upper surface 51b is a substantially flat surface facing the positive direction along the Z-axis. The upper surface 51b and the lower surface 51a are substantially parallel to each other. The upper surface 51b may be inclined with respect to the lower surface 51a. The upper surface 51b faces the third inner surface 46b at a position spaced apart from the third inner surface 46b of the covering wall 46.

The side surface 51c is a surface facing a substantially horizontal direction and connects the edge of the lower surface 51a and the edge of the upper surface 51b. The side surface 51c faces the second inner surface 45a of the peripheral wall 45 via a gap. As described above, the peripheral wall 45 and the first moving wall 51 have the center axis Ax in common. Therefore, the distance between the side surface 51c and the second inner surface 45a is set substantially uniformly.

The distance between the first inner surface 44b of the bottom wall 44 and the lower surface 51a of the first moving wall 51 is smaller than the distance between the third inner surface 46b of the covering wall 46 and the upper surface 51b of the first moving wall 51. Therefore, a diffusion space 47a wider than the gap between the first inner surface 44b and the lower surface 51a is provided between the third inner surface 46b and the upper surface 51b. The diffusion space 47a is a portion of the diffusion chamber 47 and is connected to a gap between the side surface 51c and the second inner surface 45a and to a gap between the lower surface 51a and the first inner surface 44b.

The first support 52 has a cylindrical shape extending in the positive direction along the Z-axis from the substantially central portion of the first moving wall 51, along the center axis Ax. In other words, the first support 52 is connected to the upper surface 51b of the first moving wall 51. The first support 52 passes through the supply port 42a of the tube portion 42 to protrude from an upper end of the tube portion 42 to the outside of the first member 31.

The first support 52 is arranged at a position spaced apart from the tube portion 42. That is, a gap is formed between the first support 52 and the inner surface of the supply port 42a. The distance between the first support 52 and the inner surface of the supply port 42a is substantially constant and longer than the distance between the first inner surface 44b and the lower surface 51a.

The first support 52 is connected to a first drive apparatus 55 outside the first member 31. The first drive apparatus 55 is an exemplary drive unit. The first drive apparatus 55 includes a power generating source such as a motor or an actuator, and a transmission mechanism that transmits the power generated by the power generating source to the first support 52.

For example, the transmission mechanism of the first drive apparatus 55 supports the first support 52 outside the first member 31. The first support 52 is supported by the first drive apparatus 55 so that the second member 32 is arranged at a position spaced apart from the first member 31. In other words, the second member 32 is suspended by the first drive apparatus 55 in a state of being spaced apart from the first member 31.

The first moving wall 51 includes a plurality of second openings 58. The second openings 58 may also be referred to as holes, through holes, connection ports, and communication ports. Each of the plurality of second openings 58 is a substantially circular hole extending in the direction along the Z-axis and communicating with the lower surface 51a and the upper surface 51b. In other words, the second openings 58 communicate with the gap between the first inner surface 44b and the lower surface 51a, and with the diffusion space 47a.

The diameters of the second openings 58 are substantially equal to the diameters of the straight portions 48a of the first openings 48. Furthermore, the diameters of the second openings 58 is substantially equal to the diameters of the portions having the minimum cross-sectional areas of the tapering portions 48b and are smaller than the diameters of the portions having the maximum cross-sectional areas of the tapering portions 48b. That is, the maximum cross-sectional areas of the tapering portions 48b are larger than the cross sectional areas of the second openings 58 opening on the lower surface 51a. In other words, the maximum cross-sectional areas of the tapering portions 48b are larger than the cross-sectional areas of the end portions (negative end portions along the Z-axis) facing the bottom wall 44, of the second openings 58. The sizes of the first and second openings 48 and 58 are not limited to this example.

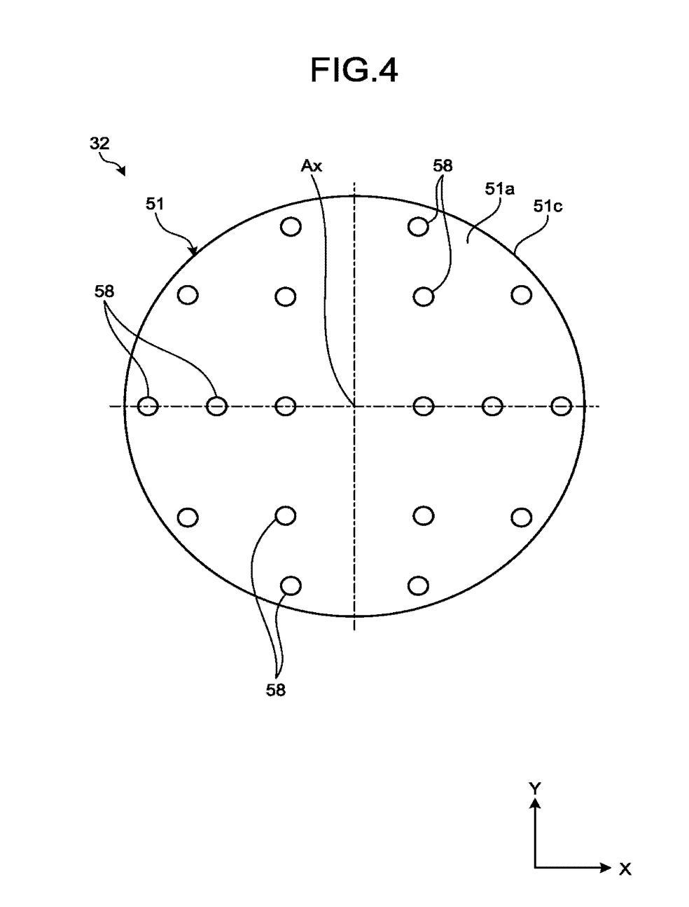

FIG. 4 is a bottom view illustrating the first moving wall 51 according to the first embodiment. As illustrated in FIGS. 3 and 4, the number of the second openings 58 is half the number of the first openings 48 in the present embodiment. The number of the second openings 58 is not limited to this example.

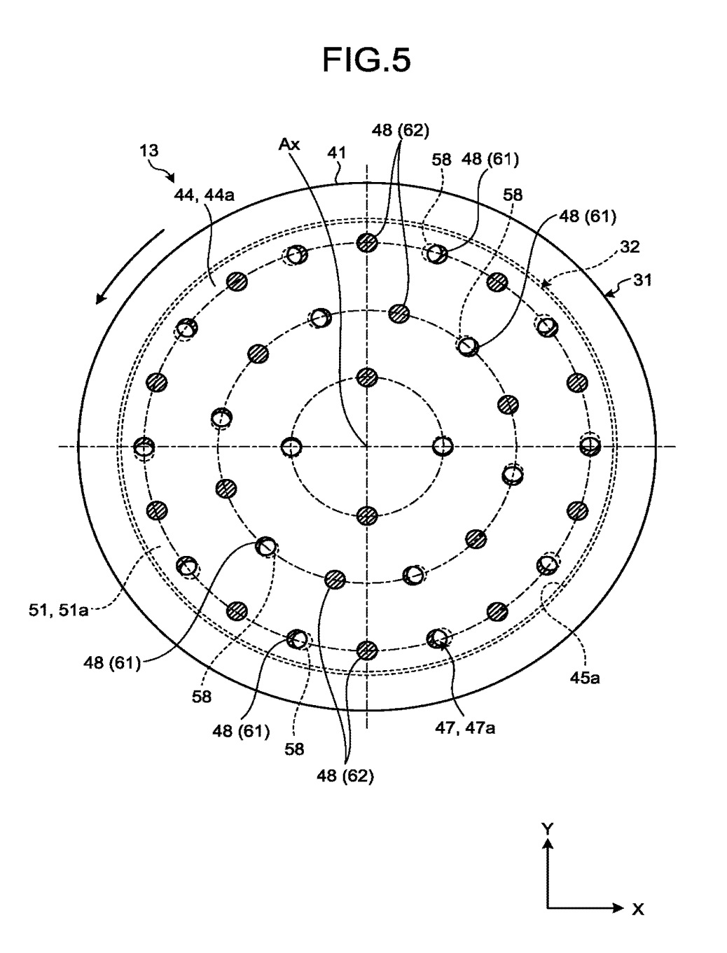

FIG. 5 is a bottom view illustrating the shower plate 13 in which the second member 32 of the first embodiment rotates. As illustrated in FIG. 5, the second member 32 rotates around the center axis Ax with respect to the first member 31 by the first drive apparatus 55 in FIG. 2, for example. In other words, the first drive apparatus 55 is capable of moving the second member 32 with respect to the first member 31. The first drive apparatus 55 rotates the second member 32 with respect to the first member 31 while maintaining the state in which the second member 32 is spaced apart from the first member 31.

As illustrated in FIG. 3, the plurality of first openings 48 includes a plurality of first ejection ports 61 and a plurality of second ejection ports 62. The first ejection ports 61 and the second ejection ports 62 have substantially the same shape, and are referred to separately for convenience of explanation. The first ejection ports 61 and the second ejection ports 62 may have mutually different shapes.

The number of the first ejection ports 61 is equal to the number of the second openings 58. Furthermore, the number of the second ejection ports 62 is equal to the number of the second openings 58. The plurality of first ejection ports 61 is arranged two-fold symmetrically (rotationally symmetric, point symmetric) around the center axis Ax. The plurality of second ejection ports 62 and the plurality of second openings 58 are also arranged two-fold symmetrically around the center axis Ax. The plurality of first ejection ports 61 is arranged so as to overlap with the plurality of second ejection ports 62 when rotated 90° around the center axis Ax. The arrangement of the plurality of second openings 58, the plurality of first ejection ports 61, and the plurality of second ejection ports 62 is not limited to this example. For example, the plurality of second openings 58, the plurality of first ejection ports 61, and the plurality of second ejection ports 62 may each be arranged three- or more-fold symmetrically around the center axis Ax. Furthermore, each of the plurality of second openings 58, the plurality of first ejection ports 61, and the plurality of second ejection ports 62 may be arranged at positions different from when they are arranged to have rotational symmetry.

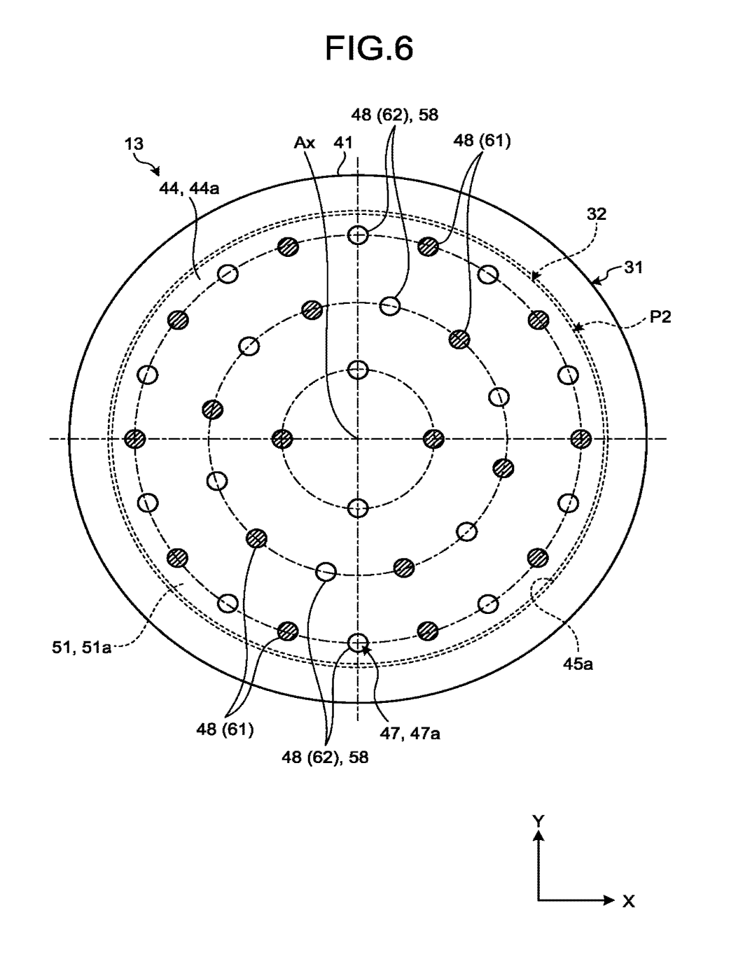

FIG. 6 is a bottom view illustrating the shower plate 13 after rotation of the second member 32 in the first embodiment. The second member 32 is rotated by the first drive apparatus 55 so as to be able to move to a first position P1 illustrated in FIG. 3 and a second position P2 illustrated in FIG. 6 with respect to the first member 31.

As illustrated in FIG. 3, plurality of first ejection ports 61 and the plurality of second openings 58 face each other at the first position 21. That is, opening ends of the first ejection ports 61 provided on the first inner surface 44b face opening ends of the second openings 58 provided on the lower surface 51a. In other words, the second openings 58 overlap with the first ejection ports 61 at the first position P1. Meanwhile, the plurality of second ejection ports 62 is covered by the first moving wall 51 at the first position P1. In FIG. 3, the second ejection ports 62 covered by the first moving wall 51 is hatched.

As illustrated in FIG. 6, the plurality of second ejection ports 62 and the plurality of second openings 58 face each other at the second position P2. That is, opening ends of the second ejection ports 62 provided on the first inner surface 44b face opening ends of the second openings 58 provided on the lower surface 51a. In other words, the second openings 58 overlap with the second ejection ports 62 at the second position P2. Meanwhile, the plurality of first ejection ports 61 is covered by the first moving wall 51 at the second position P2. In FIG. 6, the first ejection ports 61 covered by the first moving wall 51 is hatched.

As described above, the plurality of second openings 58 face the plurality of first ejection ports 61 or the plurality of second ejection ports 62 at the first position P1 or the second position P2. As illustrated in FIGS. 3 and 6, the first ejection ports 61 or the second ejection ports 62 facing the second openings 58 expose the diffusion space 47a when the bottom surface 44a of the bottom wall 44 is viewed in plan view.

For example, as illustrated in FIG. 2, the first ejection ports 61 and the second ejection ports 62 covered by the first moving wall 51 communicate with a gap between the first inner surface 44b and the lower surface 51a. Therefore, the first ejection ports 61 and the second ejection ports 62 covered by the first moving wall 51 communicate with the diffusion space 47a via the gap between the first inner surface 44b and the lower surface 51a, and a gap between the second inner surface 45a and the side surface 51c.

The total cross-sectional area of the plurality of second openings 58 is larger than the cross-sectional area of the gap between the second member 32 and the second inner surface 45a in the direction orthogonal to the Z-axis (X-Y plane). The direction orthogonal to the Z-axis is an example of a direction orthogonal to the direction in which the second openings extend.

The distance between the first inner surface 44b and the lower surface 51a is shorter than the diameters of the second openings 58. The distance between the first inner surface 44b and the lower surface 51a is shorter than the diameters of the straight portions 48a of the first openings 48.

The first gas supply apparatus 14 illustrated in FIG. 1 is connected to the supply port 42a of the shower plate 13, and supplies the first gas G1 from the supply port 42a to the diffusion space 47a of the diffusion chamber 47. The first gas supply apparatus 14 includes a tank 14a and a valve 14b. The valve 14b is an exemplary adjustment unit. The adjustment unit may be another apparatus such as a pump.

The tank 14a contains the first gas G1 and is connected to the supply port 42a via the valve 14b and a pipe. The valve 14b is opened so that the first gas supply apparatus 14 supplies the first gas G1 of the tank 14a to the supply port 42a. When the valve 14b is closed, the first gas supply apparatus 14 stops the supply of the first gas G1. Furthermore, the opening-closing amount of the valve 14b is adjusted to enable adjustment of the flow rate of the first gas G1. In this manner, the valve 14b can adjust the supply state of the first gas G1.

The second gas supply apparatus 15 is connected to the supply port 42a of the shower plate 13 and supplies the second gas G2 from the supply port 42a to the diffusion space 47a of the diffusion chamber 47. The second gas supply apparatus 15 includes a tank 15a and a valve 15b. The valve 15b is an exemplary adjustment unit.

The tank 15a contains the second gas G2 and is connected to the supply port 42a via the valve 15b and a pipe. The valve 15b is opened so that the second gas supply apparatus 15 supplies the second gas G2 of the tank 15a to the supply port 42a. When the valve 15b is closed, the second gas supply apparatus 15 stops the supply of the second gas G2. Furthermore, the opening-closing amount of the valve 15b is adjusted to enable adjustment of the flow rate of the second gas G2. In this manner, the valve 15b can adjust the supply state of the second gas G2.

The semiconductor manufacturing apparatus 10 may include a carrier gas supply apparatus in addition to the first gas supply apparatus 14 and the second gas supply apparatus 15. The carrier gas supply apparatus includes a tank containing a carrier gas such as argon, and a pipe and a valve connecting the tank with the supply port 42a. When the valve is opened, the carrier gas contained in the tank is supplied to the diffusion space 47a of the diffusion chamber 47 via the supply port 42a. For example, the carrier gas is supplied to convey the first gas G1 or the second gas G2 to the diffusion chamber 47, and is a gas that has little influence on the wafer W. For example, the carrier gas supply apparatus may be provided independently from the first gas supply apparatus 14 and the second gas supply apparatus 15, or may be provided as a portion of each of the first gas supply apparatus 14 and the second gas supply apparatus 15.

The control unit 16 includes, for example, a processing apparatus such as a CPU and a storage apparatus such as a ROM or a RAM. The control unit 16 controls, for example, the stage 12, the first gas supply apparatus 14, the second gas supply apparatus 15, and the first drive apparatus 55.

The semiconductor manufacturing apparatus 10 supplies the first gas G1 and the second gas G2 to the wafer W in the chamber 21, as will be described below. First, the control unit 16 drives the first drive apparatus 55 in FIG. 2 to rotate the second member 32 with respect to the first member 31, thereby arranging the second member 32 at the first position P1. This operation causes the plurality of second openings 58 to face the plurality of first ejection ports 61.

The first drive apparatus 55 includes a rotation angle sensor such as a rotary encoder, for example. The control unit 16 can arrange the second member 32 at the first position P1 on the basis of the rotation angle of the second member 32 obtained from the rotation angle sensor. The control unit 16 may arrange the second member 32 at the first position P1 by another means.

Next, the control unit 16 controls to open the valve 14b of the first gas supply apparatus 14 and to supply the first gas G1 to the shower plate 13. The first gas G1 is supplied to the diffusion space 47a of the diffusion chamber 47 via the supply port 42a. That is, the first gas supply apparatus 14 supplies the first gas G1 to the diffusion chamber 47 when the plurality of second openings 58 faces the plurality of first ejection ports 61. The first ejection ports 61 are an example of a first opening.

The first gas G1 is diffused in the diffusion space 47a in a direction along the X-Y plane, for example. The first gas G1 passes through the plurality of second openings 58 communicating with the diffusion space 47a and is ejected toward the wafer W from the first ejection ports 61 facing the second openings 58. As a result, the first gas G1 forms a film on a surface of the wafer W.

When a film is formed on the surface of the wafer W, the control unit 16 controls to close the valve 14b of the first gas supply apparatus 14. As a result, the supply of the first gas G1 is stopped. The first gas G1 remaining on the shower plate 13 may be discharged by the carrier gas supplied to the diffusion chamber 47, for example.

Next, the control unit 16 drives the first drive apparatus 55 so that the first drive apparatus 55 rotates the first support 52 of the second member 32. The first drive apparatus 55 rotates the second member 32 with respect to the first member 31, thereby arranging the second member 32 at the second position P2. This operation causes the plurality of second openings 58 to face the plurality of second ejection ports 62.

As described above, the first drive apparatus 55 rotates the first support 52 of the second member 32 with respect to the first member 31 so that the first moving wall 51 connected to the first support 52 rotates with respect to the first member 31. The first moving wall 51 rotates with respect to the first member 31 so that first openings 48 (first ejection ports 61) facing the second openings 58 are replaced with other first openings 48 (second ejection ports 62). In other words, the position of the first moving wall 51 with respect to the first members 31 is changed so that the first openings 48 facing the second openings 58 are replaced with other first openings 48.

Next, the control unit 16 controls to open the valve 15b of the second gas supply apparatus 15 and to supply the second gas G2 to the shower plate 13. The second gas G2 is supplied to the diffusion space 47a of the diffusion chamber 47 via the supply port 42a. That is, the second gas supply apparatus 15 supplies the second gas G2 to the diffusion chamber 47 when the plurality of second openings 58 faces the plurality of second ejection ports 62. The second ejection ports 62 are an example of another first opening. That is, the first and second gas supply apparatuses 14 and 15 supply different gases (the first gas G1 or the second gas G2) to the diffusion chamber 47 depending on first openings 48 facing the second openings 58.

The second gas G2 is diffused in the diffusion space 47a in the direction along the X-Y plane, for example. The second gas G2 passes through the plurality of second openings 58 communicating with the diffusion space 47a and is ejected toward the wafer W from the second ejection ports 62 facing the second openings 58. As a result, the second gas G2 forms a film on a surface of the wafer W.

As described above, the first gas G1 is ejected from the plurality of first ejection ports 61, while the second gas G2 is ejected from the plurality of second ejection ports 62. As a result, the first gas G1 and the second gas G2 can be ejected from their own suitable positions. As described above, for example, an oxide film and a nitride film are formed on the wafer W.

The first gas G1 and the second gas G2 having passed through the second openings 58 are ejected from the second openings 58 toward the first openings 48. The tapering portions 48b of the first openings 48 open on the bottom wall 44 toward the first moving wall 51 and face the second openings 58. The tapering portions 48b taper in a direction away from the first moving wall 51. Therefore, the first gas G1 and the second gas G2 ejected from the second openings 58 are guided by the tapering portions 48b to flow into the straight portions 48a of the first openings 48. The first gas G1 and the second gas G2 are ejected to the outside of the shower plate 13 from the straight portions 48a.

The first gas G1 and the second gas G2 supplied to the diffusion space 47a might flow into the gap between the second inner surface 45a and the side surface 51c in addition to the second openings 58 in some cases. The first gas G1 and the second gas G2 might be ejected to the outside of the shower plate 13 from the first ejection ports 61 or the second ejection ports 62 covered by the first moving wall 51 in some cases. In this case, however, the flow rates of the first gas G1 and the second gas G2 flowing into the gap between the second inner surface 45a and the side surface 51c are lower than the flow rates of the first gas G1 and the second gas G2 passing through the second openings 58. Therefore, the first gas G1 or the second gas G2 respectively ejected from the first ejection ports 61 or the second ejection ports 62 covered by the first moving wall 51 would not affect formation of the film of the wafer W. For example, the flow rate of the first gas G1 ejected by the first openings 48 (first ejection ports 61) facing the second openings 58 is higher than the flow rate of the first gas G1 ejected from the first openings 48 (second ejection ports 62) covered by the first moving wall 51.

As illustrated in FIG. 5, the first gas G1 or the second gas G2 may be supplied to the diffusion chamber 47 in a state where the second member 32 slightly rotates from the first position P1 or the second position P2. For example, in the case illustrated in FIG. 5, portions of the first ejection ports 61 are covered by the first moving wall 51. In contrast, the second ejection ports 62 are covered by the first moving wall 51, in the same manner as the case of the first position P1.

Portions of the first ejection ports 61 are covered by the first moving wall 51, resulting in narrowing the channels of the shower plate 13 (the first ejection ports 61 and the second openings 58 facing each other) compared with the case where the second member 32 is arranged at the first position P1. This configuration reduces the ejection amount of the first gas G1.

Movement of the second member 32 with respect to the first member 31 changes the amounts of the portions of the first openings 48 to be covered by the first moving wall 51. That is, movement of the second member 32 with respect to the first member 31 adjusts the flow rates of the first gas G1 and the second gas G2 ejected from the first openings 48.

The shower plate 13 is manufactured by laminate molding using a three-dimensional printer, for example. Accordingly, the second member 32 is manufactured in a state of being contained in the first member 31. The method of manufacturing the shower plate 13 is not limited to this example.

In the semiconductor manufacturing apparatus 10 according to the first embodiment described above, the diffusion chamber 47 is provided in the first member 31, and the first moving wall 51 of the second member 32 is spaced apart from the first member 31 and arranged in the diffusion chamber 47. The second member 32 allows one of the first openings 48 (first ejection port 61) facing the second openings 58 to be replaced with another of the first openings 48 (second ejection port 62) by changing the position of the second member 32 with respect to the first member 31. With this configuration, the shower plate 13 can eject the first gas G1 and the second gas G2 supplied to the common diffusion chamber 47, from a plurality of positions, making it possible to ensure a large space for the diffusion chamber 47. This leads to reduction in the pressure loss of the first gas G1 and the second gas G2 in the diffusion chamber 47, and in a case where the plurality of first openings 48 is provided, the first gas G1 and the 2 gas G2 are ejected further equally from the plurality of first openings 48. That is, the first gas G1 and the second gas G2 can be further uniformly ejected in the shower plate 13 capable of changing the ejection positions of the first gas G1 and the second gas G2. Furthermore, when one of the first openings 48 facing the second openings 58 are replaced with another of the first openings 48, generation of particles due to contact between the first member 31 and the second member 32 is suppressed. This leads to suppression of entry of particles into the diffusion chamber 47 and the first and second openings 48 and 58, and suppression of resulting hindrance of uniform ejection of the first gas G1 and the second gas G2.

Each of the plurality of first openings 48 includes the tapering portion 48b that communicates with the first inner surface 44b and tapers in a direction away from the first moving wall 51. The maximum cross-sectional areas of the tapering portions 48b are larger than the cross-sectional areas of the second openings 58 opening on the lower surface 51a. With this configuration, the first gas G1 and the second gas G2 ejected from the second openings 58 toward the first openings 48 are guided by the tapering portions 48b, leading to suppression of the first gas G1 and the second gas G2 flowing into the gap between the bottom wall 44 and the first moving wall 51.

The distance between the first inner surface 44b and the second member 32 is shorter than the distance between the third inner surface 46b and the second member 32. This facilitates diffusion of the first gas G1 and the second gas G2 in the diffusion chamber 47 (diffusion space 47a) between the third inner surface 46b and the second member 32. Furthermore, it is possible to suppress spreading of the first gas G1 and the second gas G2 coming out of the second openings 58 in the gap between the first inner surface 44b and the second member 32, leading to suppression of the ejection of the first gas G1 and the second gas G2 from the undesired first openings 48.

The second member 32 allow one of the first openings 48 facing the second openings 58 to be replaced with another of the first openings 48 by rotating with respect to the first member 31. Accordingly, one of the first openings 48 facing the second openings 58 can be easily replaced with another of the first openings 48.

The total cross-sectional area of the plurality of second openings 58 is larger than the cross-sectional area of the gap between the second member 32 and the second inner surface 45a in a direction orthogonal to the direction in which the second openings 58 extend. With this configuration, it is possible to suppress spreading of the first gas G1 and the second gas G2 supplied to the diffusion chamber 47 to the gap between the first member 31 and the second member 32 through the gap between the second member 32 and the second inner surface 45a, leading to suppression of the ejection of the first gas G1 and the second gas G2 from the undesired first openings 48.

The second member 32 is supported by the first support 52 outside the first member 31 to be arranged at a position spaced apart from the first member 31. With this configuration, it is possible to suppress entry of the particles generated by the contact between the first support 52 and the first drive apparatus 55 supporting the first support 52 into the diffusion chamber 47, or the first and second openings 48 and 58.

The first drive apparatus 55 is connected to the first support 52 outside the first member 31 to move the first support 52 with respect to the first member 31, thereby replacing one of the first openings 48 facing the second openings 58 with another of the first openings 48. This leads to suppression of entry of the particles generated by driving of the first support 52 by the first drive apparatus 55 into the diffusion chamber 47 and the first and second openings 48 and 58.

The first and second gas supply apparatuses 14 and 15 supply the first gas G1 to the diffusion chamber 47 when the second openings 58 face the first ejection ports 61 and supply the second gas G2 to the diffusion chamber 47 when the second openings 58 face the second ejection ports 62. This enables the semiconductor manufacturing apparatus 10 to change the positions of the first openings 48 to eject the first gas G1 and the positions of the first openings 48 to eject the second gas G2, making it possible to eject the first gas G1 and the second gas G2 from appropriate positions.

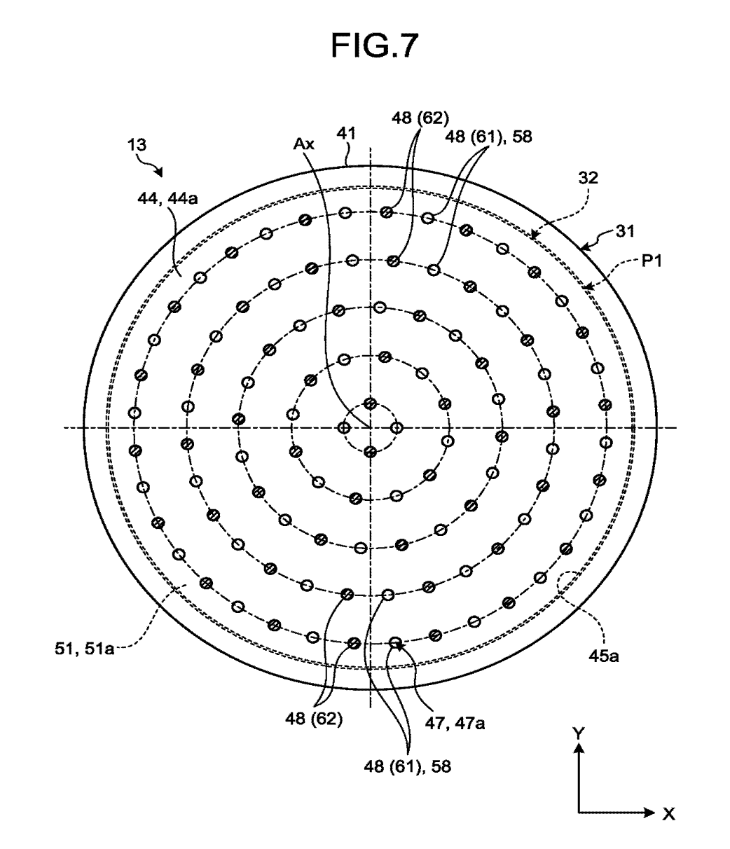

FIG. 7 is a bottom view illustrating the shower plate 13 according to a modification of the first embodiment. As illustrated in FIGS. 3 and 7, the plurality of first openings 48 is arranged on a plurality of concentric circles indicated by the one-dot chain line. For example, the number of first openings 48 arranged on each of circles from the innermost circle to the outer circle increases as four, twelve, twenty, twenty eight, thirty six, etc. By arranging the first openings 48 in this manner, it is possible to arrange the plurality of first openings 48 more equally. The number and arrangement of the first openings 48 are not limited to this example.

### Second Embodiment

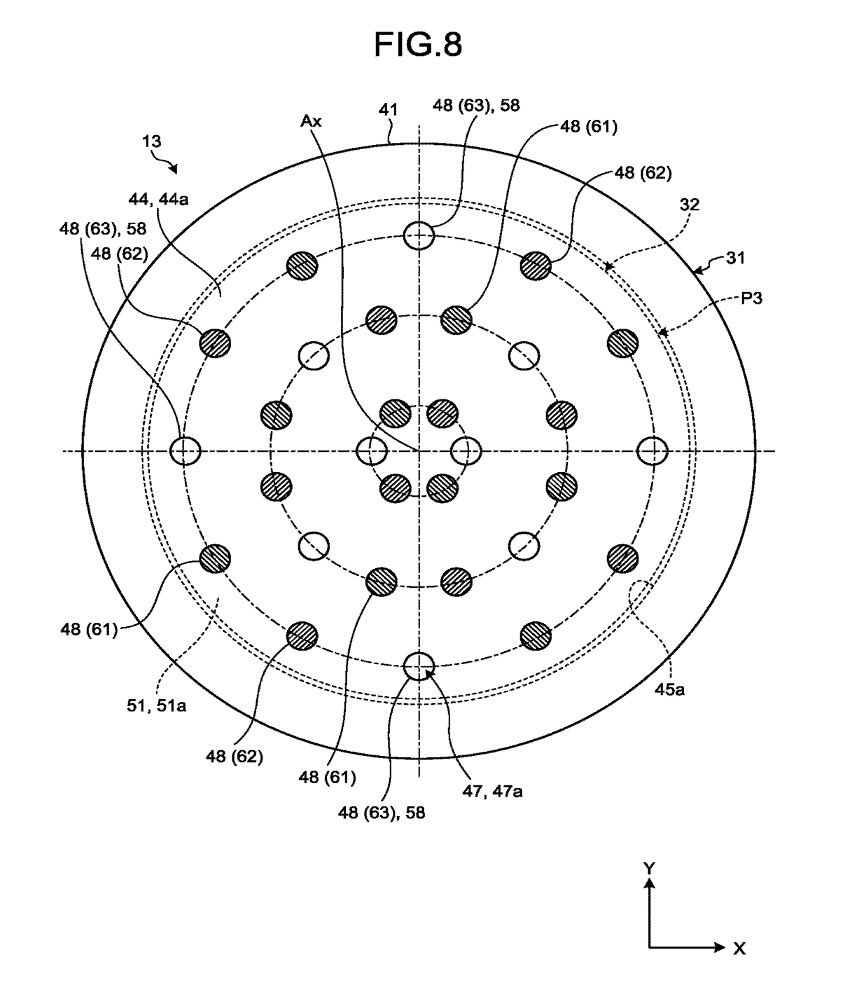

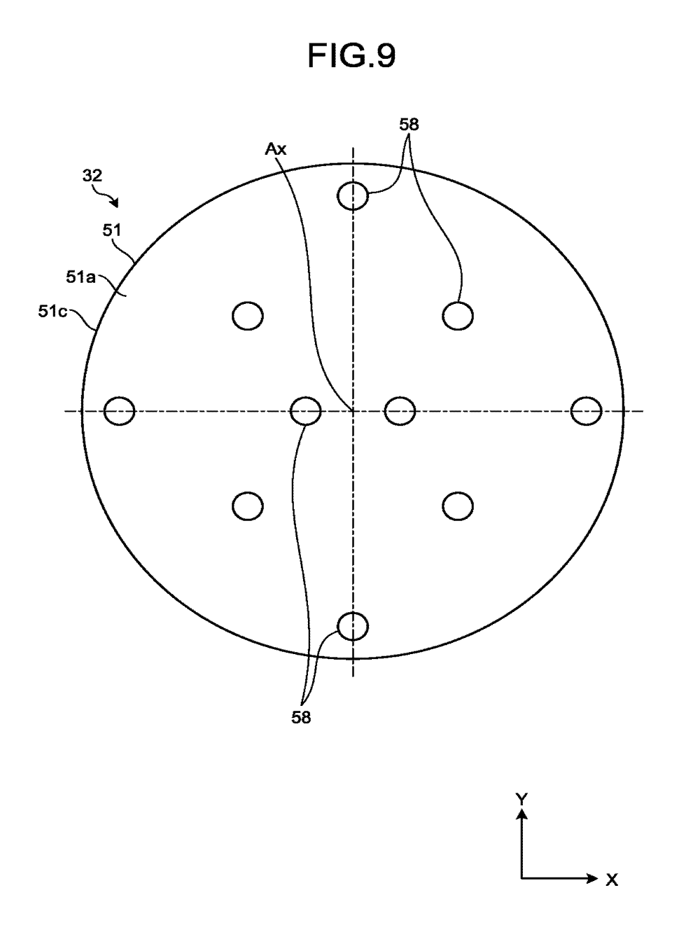

Hereinafter, a second embodiment will be described with reference to FIGS. 8 and 9. In the following description of a plurality of embodiments, the same reference numerals are given to constituent elements having functions similar to the functions of the already described constituent elements, and further description will be omitted in some cases. Moreover, the plurality of constituent elements denoted by the same reference numerals do not necessarily have all functions and properties in common, and may have different functions and properties according to each of the embodiments.

FIG. 8 is a bottom view of the shower plate 13 according to the second embodiment. FIG. 9 is a bottom view illustrating the first moving wall 51 in the second embodiment. As illustrated in FIG. 8, in the second embodiment, the plurality of first openings 48 includes the plurality of first ejection ports 61, the plurality of second ejection ports 62, and a plurality of third ejection ports 63. The first to third ejection ports 61 to 63 have substantially the same shape and are referred to separately for convenience of explanation. The first to third ejection ports 61 to 63 may have mutually different shapes.

The number of the third ejection ports 63 is equal to the number of the second openings 58. Furthermore, the number of the third ejection ports 63 is equal to the number of the first ejection ports 61 and equal to the number of the second ejection ports 62. The plurality of third ejection ports 63 are arranged two-fold symmetrically around the center axis Ax. The arrangement of the plurality of third ejection ports 63 is not limited to this example. For example, the plurality of third ejection ports 63 may be arranged three- or more-fold symmetrically around the center axis Ax. Furthermore, the plurality of third ejection ports 63 may be arranged at positions different from when they are arranged to have rotational symmetry.

In the second embodiment, the plurality of first ejection ports 61 is arranged so as to overlap with the plurality of second ejection ports 62 when rotated 60° around the center axis Ax. In addition, the plurality of first ejection ports 61 is arranged so as to overlap with the plurality of third ejection ports 63 when rotated 120° around the center axis Ax.

The first moving wall 51 of the second member 32 is rotated with respect to the first member 31 by the first drive apparatus 55 so as to be able to move to the first position P1, the second position P2, and a third position P3. FIG. 8 illustrates the second member 32 arranged at the third position P3.

At the first position P1, the first ejection ports 61 face the second openings 58, and the second ejection ports 62 and the third ejection ports 63 are covered by the first moving wall 51. At the second position P2, the second ejection ports 62 face the second openings 58, and the first ejection ports 61 and the third ejection ports 63 are covered by the first moving wall 51. At the third position P3, the third ejection ports 63 face the second openings 58, and the first ejection ports 61 and the second ejection ports 62 are covered by the first moving wall 51. In FIG. 8, the first ejection ports 61 and the second ejection ports 62 covered by the first moving wall 51 are differently hatched.

In the semiconductor manufacturing apparatus 10 according to the second embodiment described above, the second member 32 allows one of the first openings 48 (first ejection port 61) facing the second openings 58 to be replaced with another of the first openings 48 (second ejection port 62) by moving with respect to the first member 31, and in addition, allows the one to be replaced with still another of the first openings 48 (third ejection port 63). With this configuration, the shower plate 13 can eject a plurality of types of gas (the first gas G1, the second gas G2, and still another gas) supplied to the common diffusion chamber 47, from a plurality of positions, making it possible to ensure a large space for the diffusion chamber 47. Accordingly, the pressure loss of the first gas G1 and the second gas G2 in the diffusion chamber 47 is reduced, and in a case where the plurality of first openings 48 is provided, the plurality of types of gas is ejected from the plurality of first ejection openings 48 further equally.

### Third Embodiment

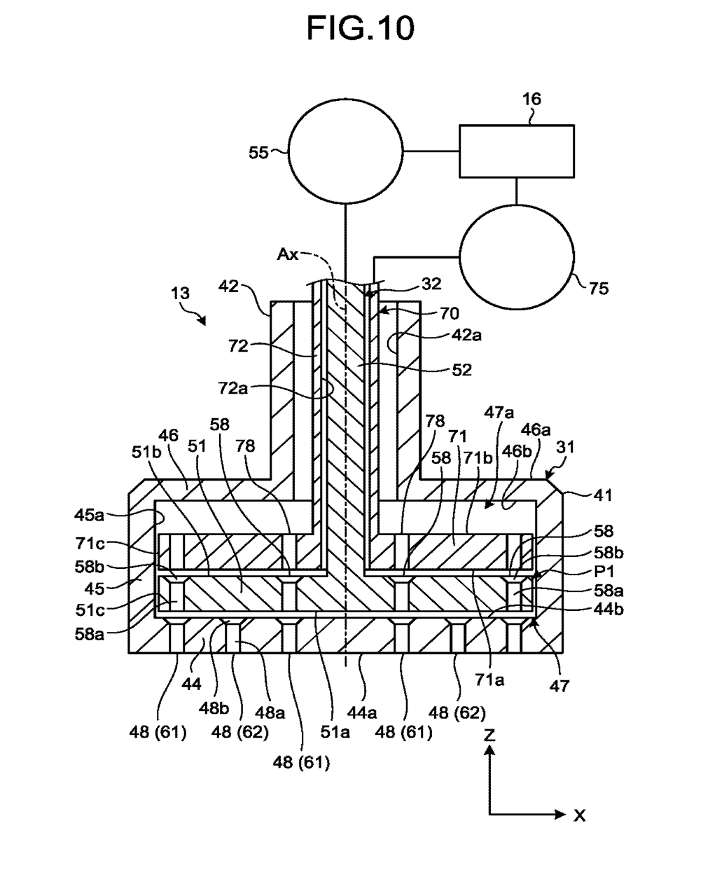

Hereinafter, a third embodiment will be described with reference to FIG. 10. FIG. 10 is a cross-sectional view of the shower plate 13 according to the third embodiment. As illustrated in FIG. 10, the shower plate 13 of the third embodiment includes a third member 70.

The third member 70 is formed of a material resistant to the first and second gases G1 and G2, for example. The third member 70 is arranged at a position spaced apart from the first member 31 and the second member 32. The third member 70 is spaced apart from the first member 31 and the second member 32 at least inside the first member 31. The third member 70 includes a second moving wall 71 and a second support 72. The second moving wall 71 is an exemplary third wall.

The second moving wall 71 has a substantially disk shape spreading on the X-Y plane. The second moving wall 71 has a center axis Ax in common with the bottom wall 44, the covering wall 46, the peripheral wall 45, and the first moving wall 51. The second moving wall 71, the bottom wall 44, the covering wall 46, the peripheral wall 45, and the first moving wall 51 may have mutually different center axes.

The second moving wall 71 is arranged in the diffusion chamber 47 at a position spaced apart from the first member 31 and the second member 32. That is, the second moving wall 71 is smaller than the diffusion chamber 47 and contained inside the first member 31. The second moving wall 71 includes a lower surface 71a, an upper surface 71b, and a side surface 71c.

The lower surface 71a is a substantially flat surface facing the negative direction along the Z-axis. The lower surface 71a faces the upper surface 51b of the first moving wall 51 via a gap. Accordingly, the first moving wall 51 is located between the bottom wall 44 and the second moving wall 71 in the direction along the Z-axis.

The upper surface 71b is a substantially flat surface facing the positive direction along the Z-axis. The upper surface 71b faces the third inner surface 46b at a position spaced apart from the third inner surface 46b of the covering wall 46. The side surface 71c is a surface facing a substantially horizontal direction and connects an edge of the lower surface 71a with an edge of the upper surface 71b. In the third embodiment, the diffusion space 47a is provided between the third inner surface 46b and the upper surface 71b.

The side surface 71c faces the second inner surface 45a of the peripheral wall 45 via a gap. The distance between the side surface 71c and the second inner surface 45a is substantially equal to the distance between the side surface 51c of the first moving wall 51 and the second inner surface 45a and is set substantially uniformly.

The second support 72 has a cylindrical shape extending in the positive direction along the Z-axis from the substantially central portion of the second moving wall 71, along the center axis Ax. The second support 72 passes through the supply port 42a of the tube portion 42 to protrude from the upper end of the tube portion 42 to the outside of the first member 31.

An insertion hole 72a is provided inside the second support 72. The insertion hole 72a is inserted through an upper end of the second support 72 and the lower surface 71a of the second moving wall 71. The first support 52 passes through the insertion hole 72a in a state of being spaced apart from the third member 70.

The second support 72 is arranged at a position spaced apart from the tube portion 42. The distance between the second support 72 and the inner surface of the supply port 42a is longer than the distance between the first inner surface 44b and the lower surface 51a.

The second support 72 is connected to a second drive apparatus 75 outside the first member 31. The second drive apparatus 75 includes a power generating source such as a motor or an actuator, and a transmission mechanism that transmits the power generated by the power generation source to the second support 72.

For example, the transmission mechanism of the second drive apparatus 75 supports the second support 72 outside the first member 31. The second support 72 is supported by the second drive apparatus 75 so that the third member 70 is arranged at a position spaced apart from the first member 31 and the second member 32.

The second moving wall 71 includes a plurality of third openings 78. Each of the plurality of third openings 78 is a substantially circular hole extending in the direction along the Z-axis and communicating with the lower surface 71a and the upper surface 71b. In other words, the third openings 78 communicate with the gap between the lower surface 71a and the upper surface 51b of the first moving wall 51, and with the diffusion space 47a.

The diameters of the third openings 78 re substantially equal to the diameters of the second openings 58. The number of the third openings 78 is equal to the number of the second openings 58. The sizes and the number of the third openings 78 are not limited to this example.

The third member 70 rotates around the center axis Ax with respect to the first member 31 by the second drive apparatus 75, for example. The second drive apparatus 75 rotates the third member 70 with respect to the first member 31 while maintaining the state in which the third member 70 is spaced apart from the first member 31 and the second member 32.

The third member 70 is rotated such that the third openings 78 face the second openings 58 when the second member 32 is located at the first position P1 or the second position P2. That is, the third member 70 is rotated by the second drive apparatus 75 so as to follow the second member 32.

Meanwhile, the first gas G1 or the second gas G2 might be supplied to the diffusion chamber 47 in some cases in a state where the second member 32 slightly rotates from the first position P1 or the second position P2. For example, in a case where the second member 32 is arranged at a position slightly rotated from the first position P1, the third openings 78 are arranged at positions overlapping with the first ejection ports 61 by the rotation of the third member 70 with respect to the second member 32. This causes portions of the first ejection ports 61 and portions of the third openings 78 to be covered by the first moving wall 51.

The first moving wall 51 covers portions of the first ejection ports 61, leading to the reduction in the ejection amount of the first gas G1. Furthermore, the third openings 78 are arranged at positions overlapping with the first ejection ports 61, allowing the direction in which the first gas G1 is ejected to be closer to the Z-axis. That is, the third member 70 is moved relative to the second member 32, thereby adjusting the direction in which the first gas G1 and the second gas G2 are ejected from the first openings 48.

In the third embodiment, the plurality of second openings 58 includes straight portions 58a and tapering portions 58b. The straight portions 58a are substantially circular holes communicating with the lower surface 51a of the first moving wall 51. The straight portions 58a extend substantially linearly in the direction along the Z-axis. The tapering portions 58b are substantially truncated conical holes communicating with the upper surface 51b of the first moving wall 51. The tapering portions 58b may have another shape. The tapering portions 58b taper in a direction from the upper surface 51b toward the lower surface 51a. That is, portions having the maximum cross-sectional areas of the tapering portions 58b open on the upper surface 51b. On the other hand, the portions having the minimum cross-sectional areas of the tapering portions 58b are connected to the straight portions 58a.

The first gas G1 and the second gas G2 having passed through the third openings 78 are ejected from the third openings 78 toward the second openings 58. The tapering portions 58b of the second openings 58 face the third openings 78. The tapering portions 58b taper in a direction away from the second moving wall 71. Therefore, the first gas G1 and the second gas G2 ejected from the third openings 78 are guided by the tapering portions 58b to flow into the straight portions 58a of the second openings 58. The first gas G1 and the second gas G2 are ejected to the outside of the shower plate 13 from the straight portions 58a via the first openings 48. In this manner, the first gas G1 and the second gas G2 ejected from the third openings 78 toward the second openings 58 are guided by the tapering portions 58b, leading to suppression of the first gas G1 and the second gas G2 flowing into the gap between the first moving wall 51 and the second moving wall 71.

In the semiconductor manufacturing apparatus 10 according to the third embodiment described above, the third member 70 moves with respect to the second member 32, whereby the third openings 78 can be arranged at a position overlapping with the first openings 48 in a case where the first moving wall 51 covers a portion of the first openings 48 (first ejection ports 61). This enables adjustment of the direction in which the first gas G1 and the second gas G2 are ejected from the first openings 48.

### Fourth Embodiment

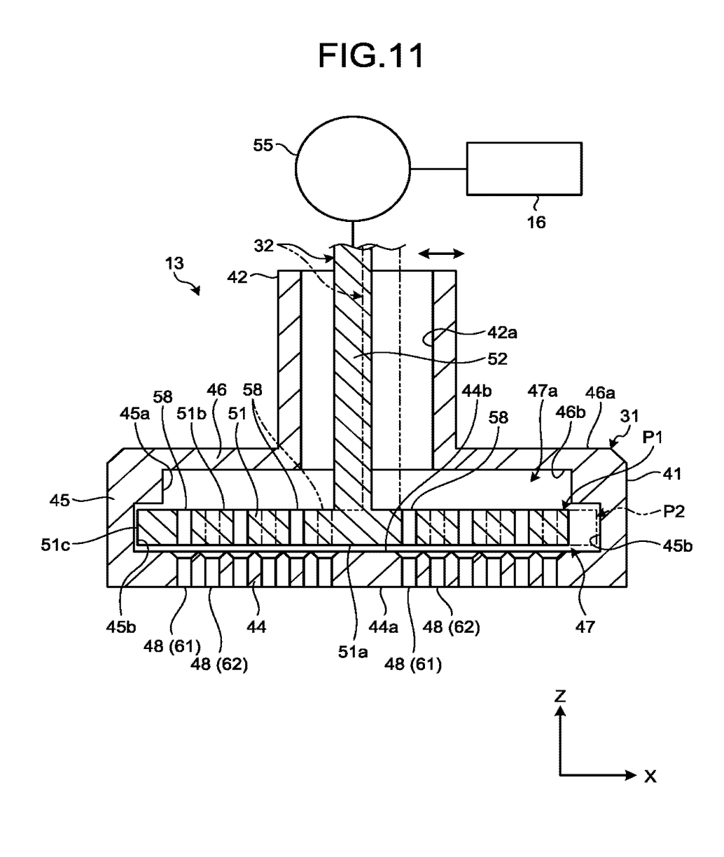

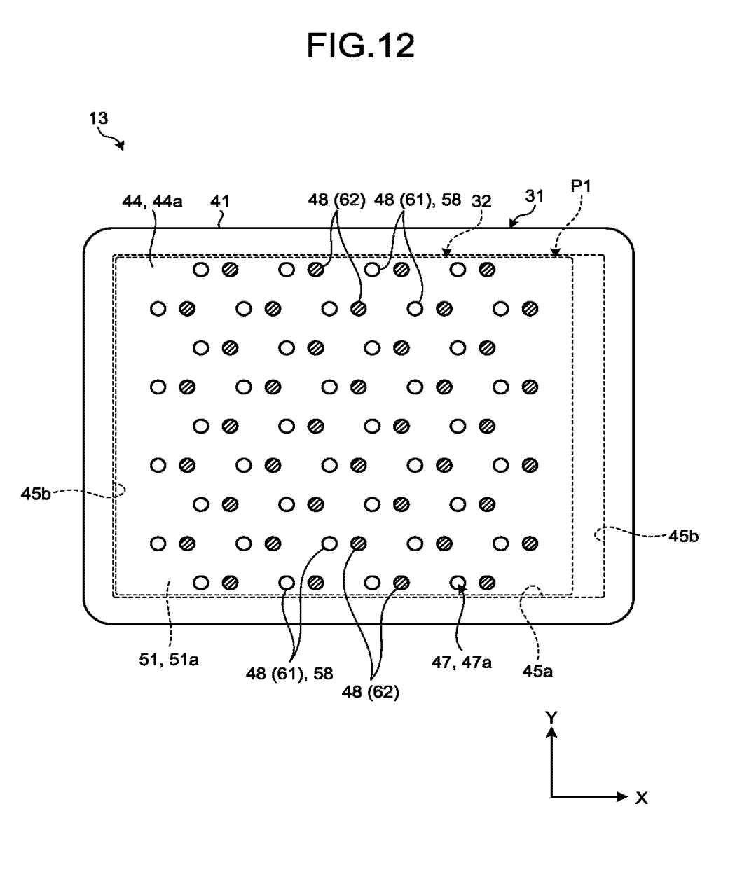

Hereinafter, a fourth embodiment will be described with reference to FIGS. 11 and 12. FIG. 11 is a cross-sectional view illustrating the shower plate 13 according to the fourth embodiment. FIG. 12 is a bottom view illustrating the shower plate 13 in the fourth embodiment.

In the fourth embodiment, the diffuser 41 has a substantially rectangular plate shape extending in the direction along the X-axis while spreading on the X-Y plane. The first moving wall 51 has a substantially rectangular plate shape extending in the direction along the X-axis while spreading on the X-Y plane. The diffuser 41 and the first moving wall 51 may each have a substantially disk shape in the same manner as in the first to third embodiments.

The second member 32 is translated with respect to the first member 31 in the direction along the X-axis, by the first drive apparatus 55, for example. That is, the second member 32 is moved with respect to the first member 31, substantially without rotation or change of shape. In other words, the first drive apparatus 55 is capable of moving the second member 32 with respect to the first member 31. The first drive apparatus 55 translates the second member 32 with respect to the first member 31 to the first position P1 and the second position P2 while maintaining the state in which the second member 32 is spaced apart from the first member 31. In FIG. 11, the second member 32 in the first position P1 is indicated by a solid line and the second member 32 in the second position P2 is indicated by a two-dot chain line.

In the same manner as in the first embodiment, the first ejection ports 61 and the second openings 58 face each other at the first position P1, and the plurality of second ejection ports 62 is covered by the first moving wall 51. Meanwhile, at the second position P2, the second ejection ports 62 and the second openings 58 face each other, and the first ejection ports 61 are covered by the first moving wall 51. In FIG. 12, the second ejection ports 62 covered with the first moving wall 51 are hatched.

The first drive apparatus 55 translates the first support 52 of the second member 32 with respect to the first member 31, so that the first moving wall 51 connected to the first support 52 is translated with respect to the first member 31. The first moving wall 51 is translated with respect to the first member 31 to replace first openings 48 (first ejection ports 61) facing the second openings 58 with other first openings 48 (second ejection ports 62).

The first gas G1 or the second gas G2 may be supplied to the diffusion chamber 47 in a state where the second member 32 has slightly moved from the first position P1 or the second position P2. For example, in a case where the second member 32 has slightly moved from the first position P1, portions of the first ejection ports 61 is covered by the first moving wall 51. Additionally, the second ejection ports 62 are covered by the first moving wall 51, in the same manner as the case of the first position P1.

In the fourth embodiment, the partially covered amounts in the portions of the first ejection ports 61 by the first moving wall 51 are equal between the plurality of first ejection ports 61. This makes it possible to evenly adjust the flow rates and inclination angles of the first gas G1 and the second gas G2 ejected from the plurality of first ejection ports 61.

As illustrated in FIG. 11, two recessed surfaces 45b are provided on the peripheral wall 45. The recessed surface 45b is a portion recessed in the direction along the X-axis from the second inner surface 45a. When the second member 32 is located in the first position P1, a portion of the first moving wall 51 is contained in a recess defined by one recessed surface 45b. When the second member 32 is located at the second position P2, a portion of the first moving wall 51 is contained in a recess defined by the other recessed surface 45b.

The total cross-sectional area of the plurality of second openings 58 is larger than the cross-sectional area of the gap between the recessed surface 45b and the second member 32. This configuration suppress entry of the first gas G1 and the second gas G2 supplied to the diffusion space 47a into the gap between the recessed surface 45b and the second member 32.

In the semiconductor manufacturing apparatus 10 according to the fourth embodiment described above, the second member 32 allows one of the first openings 48 facing the second openings 58 to be replaced with another of the first openings 48 by being translated with respect to the first member 31. With this configuration, in a case where a plurality of second openings 58 is provided, the relative positions of the respective second openings 58 and the first openings 48 are substantially equalized, making it possible to further uniformize the ejection amount and the inclination angle of the first gas G1 and the second gas G2 ejected from the first openings 48.

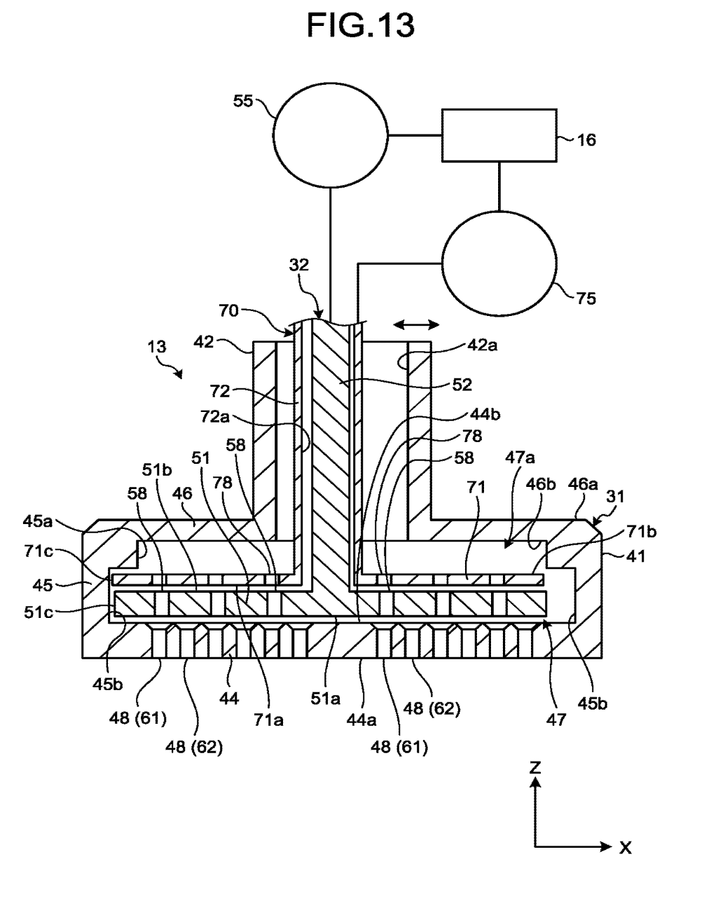

FIG. 13 is a cross-sectional view of the shower plate 13 according to a modification of the fourth embodiment. As illustrated in FIG. 13, the semiconductor manufacturing apparatus 10 in the fourth embodiment may include the third member 70 and the second drive apparatus 75.

For example, the third member 70 may be translated with respect to the second member 32 so that the third openings 78 are arranged at positions overlapping with the first openings 48 in a case where the first moving wall 51 covers portions of the first openings 48 (first ejection ports 61). By arranging the third openings 78 at positions overlapping with the first ejection ports 61, the direction in which the first gas G1 is ejected is closer to the Z-axis. Furthermore, the partially covered amounts in the portions of the first ejection ports 61 by the first moving wall 51 are equal between the plurality of first ejection ports 61. This makes it possible to further uniformly adjust the flow rates and inclination angles of the first gas G1 and the second gas G2 ejected from the plurality of first ejection ports 61.

According to at least one embodiment described above, a second member includes a second wall provided with a second opening and arranged in a room inside a first member, and is arranged at a position spaced apart from the first member. The second member allows one of first openings facing the second openings to be replaced with another of the first openings by changing the position of the second member with respect to the first member. This allows the fluid to be more equally ejected from the plurality of first openings. Furthermore, when one of the first openings facing the second openings is replaced with another of the first openings, generation of particles due to contact between the first member and the second member is suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, in each of the embodiments, the first drive apparatus 55 rotates the second member 32. Alternatively, the first drive apparatus 55 may rotate the first member 31 to move the second member 32 with respect to the first member 31.

What is claimed is:

1. A shower plate comprising:
a first member including a first wall provided with a plurality of first openings and internally including a room with which the first openings communicate; and
a second member including a second wall provided with a second opening and arranged in the room, the second member being arranged at a position spaced apart from the first member, and allowing one of the first openings facing the second opening to be replaced with another of the first openings by changing a position of the second member with respect to the first member.

2. The shower plate according to claim 1, wherein the second member allows one of the first openings facing the second opening to be replaced with another of the first openings by rotating with respect to the first member.

3. The shower plate according to claim 1, wherein the second member allows one of the first openings facing the second opening to be replaced with another of the first openings by being translated with respect to the first member.

4. The shower plate according to claim 1, wherein
the first wall includes a first surface that faces the second wall and with which the first openings communicates,
the first member includes a second surface facing the first surface, and
a distance between the first surface and the second member is shorter than a distance between the second surface and the second member.

5. The shower plate according to claim 1, wherein
the second opening includes a plurality of second openings provided in the second wall, and
a total cross-sectional area of the second openings is larger than a cross-sectional area of a gap between the second member and an inner surface of the room in a direction orthogonal to a direction in which the second openings extend.

6. The shower plate according to claim 1, wherein
each of the first openings includes a tapering portion opening on the first wall toward the second wall and tapering in a direction away from the second wall, and
a maximum cross-sectional area of the tapering portion is larger than a cross-sectional area of an end portion facing the first wall, of the second opening.

7. The shower plate according to claim 1, further comprising a third member including a third wall provided with a third opening and arranged in the room, the third member being arranged at a position spaced apart from the first member and the second member, and the third member being capable of arranging the third opening at a position overlapping with one of the first openings in a case where the second wall covers a portion of the one of the first openings, by moving with respect to the second member.

8. The shower plate according to claim 1, wherein
a supply port communicating with the room is provided in the first member, and
the second member includes a support connected to the second wall, passing through the supply port and supported outside the first member, the second member being arranged at the position spaced apart from the first member by the support being supported.

9. A processing apparatus comprising:
an arrangement unit to arrange a target object;
the shower plate according to claim 1, in which a fluid is supplied to the room and that ejects the fluid to the target object arranged on the arrangement unit;
an adjustment unit capable of adjusting a supply state of the fluid supplied to the room; and
a drive unit to move the second member with respect to the first member to replace one of the first openings facing the second opening with another of the first openings.

10. The apparatus according to claim 9, further comprising a supply unit that includes the adjustment unit and supplies the fluid to the room, wherein
the supply unit supplies a first fluid to the room when the second opening faces one of the first openings, and supplies a second fluid to the room when the second opening faces another of the first openings.

11. An ejection method comprising:
moving a second wall provided with a second opening and arranged in a room at a position spaced apart from a first member including a first wall provided with a plurality of first openings and internally including the room with which the first openings communicates, with respect to the first member, to replace one of the first openings facing the second opening with another of the first openings; and
supplying a fluid to the room.
